(19) United States
(12) Patent Application Publication
(10) Pub. No.: US 2025/0252918 A1
(43) Pub. Date: Aug. 7, 2025

(54) Display Apparatus

(71) Applicant: LG Display Co., Ltd., Seoul (KR)

(72) Inventor: Min-Ji Han, Paju-si (KR)

(21) Appl. No.: 18/952,569

(22) Filed: Nov. 19, 2024

(30) Foreign Application Priority Data
Feb. 3, 2024 (KR) 10-2024-0026404

(51) Int. Cl. G09G 3/3233; H10K 59/131

(52) U.S. Cl. CPC G09G 3/3233; H10K 59/131; G09G 2300/0819; G09G 2300/0842; G09G 2300/0861; G09G 2320/0233; G09G 2340/14

(57) ABSTRACT

A display apparatus includes: a display panel with a hole and including a display region with pixels; and initialization voltage lines extending along horizontal lines of the display region, and providing an initialization voltage to the pixels, wherein the display region includes a first display region including first and second regions arranged on both sides in a horizontal direction with the hole therebetween, and a second display region including third and fourth regions arranged on both sides in a vertical direction with the hole therebetween, wherein the initialization voltage lines include first to fourth initialization voltage lines respectively arranged in the first to fourth regions, wherein the first region includes a plurality of connection groups in each of which adjacent first initialization voltage lines are commonly connected, and wherein the second region includes a plurality of connection groups in each of which adjacent second initialization voltage lines are commonly connected.

### CROSS REFERENCE TO RELATED APPLICATION

The present application claims the priority benefit of Republic of Korea Patent Application No. 10-2024-0026404 filed on Feb. 23, 2024, which is hereby incorporated by reference in its entirety.

### BACKGROUND

### Field of Technology

The present disclosure relates to a display apparatus.

### Discussion of the Related Art

As an information society develops, demand for display apparatuses for displaying images is increasing in various forms, and recently, various flat display apparatuses such as organic light emitting display apparatuses and liquid crystal display apparatuses are being utilized.

Here, the organic light emitting display apparatus has advantages of being small, light, thin, and low power, and are being widely used.

Recently, the organic light emitting display apparatus is applied as a display apparatus for smartphone, etc., and a hole is formed in a display region to place an optical component such as a camera therein.

As the hole is formed in the display region, deterioration of image quality occurs between a portion of the display region including the hole and a portion of the display region located on an upper side and on a lower side of the hole and not including the hole.

### SUMMARY

An advantage of the present disclosure is to provide a display apparatus that can improve deterioration of image quality caused by an increase in luminance deviation along a horizontal direction in a portion of a display region including a hole.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display apparatus includes: a display panel with a hole formed therein and including a display region in which pixels are arranged; and initialization voltage lines that extend along horizontal lines of the display region, respectively, and provide an initialization voltage to the pixels, wherein the display region includes a first display region including first and second regions arranged on both sides in a horizontal direction with the hole therebetween, and a second display region including third and fourth regions arranged on both sides in a vertical direction with the hole therebetween, wherein the initialization voltage lines include first to fourth initialization voltage lines respectively arranged in the first to fourth regions, wherein the first region includes a plurality of connection groups in each of which adjacent first initialization voltage lines are commonly connected, and wherein the second region includes a plurality of connection groups in each of which adjacent second initialization voltage lines are commonly connected.

In another embodiment, a display apparatus includes: a display panel with a hole formed therein and including a display region in which pixels are arranged; and initialization voltage lines that extend along horizontal lines of the display region, respectively, and provide an initialization voltage to the pixels, wherein the display region includes a first display region with the hole located therein and extending in a horizontal direction, and a second display region outside the first display region, and wherein each of both portions of the first display region on both sides of the hole includes a plurality of connection groups in each of which the initialization voltage lines of adjacent horizontal lines are commonly connected.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view schematically illustrating a display apparatus according to a first embodiment of the present disclosure;

FIG. 2 is a circuit diagram schematically illustrating an example of a pixel according to a first embodiment of the present disclosure;

FIG. 3 is a view schematically illustrating an initialization voltage line and a voltage transmission line formed in a display panel according to a first embodiment of the present disclosure;

FIG. 4 is a view schematically illustrating an example of an arrangement structure of an initialization voltage line formed in a hole-in display region and a non-hole display region according to a first embodiment of the present disclosure;

FIG. 5 is a view schematically illustrating a circuit configuration of an initialization voltage line formed in a hole-in display region and a non-hole display region according to a first embodiment of the present disclosure;

FIG. 6 is a view schematically illustrating another example of an arrangement structure of an initialization voltage line formed in a hole-in display region and a non-hole display region according to a first embodiment of the present disclosure;

FIG. 7 is a view schematically illustrating a circuit configuration of an initialization voltage line formed in a hole-in display region and a non-hole display region according to another example of FIG. 6;

FIG. 8 is a view illustrating simulation results comparing pixel currents in arrangement structures of initialization voltage lines according to a first embodiment of the present disclosure and a comparative example; and

FIG. 9 is a view schematically illustrating an example of an arrangement structure of an initialization voltage line formed in a hole-in display region and a non-hole display region of a display panel according to a second embodiment of the present disclosure.

### DETAILED DESCRIPTION

Advantages and features of the present disclosure and methods of achieving them will be apparent with reference to the embodiments described below in detail with the accompanying drawings. However, the present disclosure is not limited to the embodiments disclosed below, but can be realized in a variety of different forms, and only these embodiments allow the present disclosure to be complete. The present disclosure is provided to fully inform the scope of the disclosure to the skilled in the art of the present disclosure, and the present disclosure may be defined by the scope of the claims.

The shapes, sizes, proportions, angles, numbers, and the like disclosed in the drawings for explaining the embodiments of the present disclosure are illustrative, and the present disclosure is not limited to the illustrated matters. The same reference numerals refer to the same components throughout the description.

Furthermore, in describing the present disclosure, if it is determined that a detailed description of the related known technology unnecessarily obscure the subject matter of the present disclosure, the detailed description thereof can be omitted. When ‘comprising’, ‘including’, and ‘having’ and the like are used in this disclosure, other parts can be added unless ‘only’ is used. When a component is expressed in the singular, cases including the plural are included unless specific statement is described.

In interpreting the components, even if there is no separate explicit description, it is interpreted as including a margin range.

In the case of a description of a positional relationship, for example, when the positional relationship of two parts is described as ‘on’, ‘over’, ‘above’, ‘below’, ‘beside’, ‘under’, and the like, one or more other parts can be positioned between such two parts unless ‘right’ or ‘directly’ is used.

In the case of a description of a temporal relationship, for example, when a temporal precedence is described as ‘after’, ‘following’, ‘before’, and the like, cases that are not continuous can be included unless ‘directly’ or ‘immediately’ is used.

In describing components of the present disclosure, terms such as first, second and the like can be used. These terms are only for distinguishing the components from other components, and an essence, order, sequence, or number of the components is not limited by the terms.

Respective features of various embodiments of the present disclosure can be partially or wholly connected to or combined with each other and can be technically interlocked and driven variously, and respective embodiments can be independently implemented from each other or can be implemented together with a related relationship.

Hereinafter, embodiments of the present disclosure are described in detail with reference to the drawings. Meanwhile, in the following embodiments, the same and like reference numerals are assigned to the same and like components, and detailed descriptions thereof may be omitted.

### First Embodiment

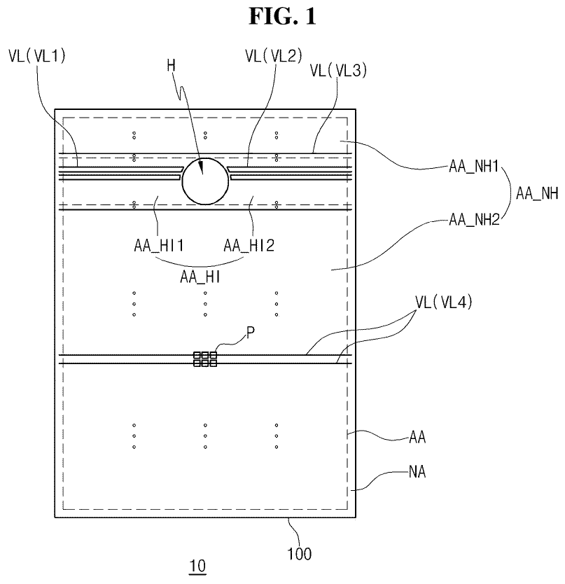

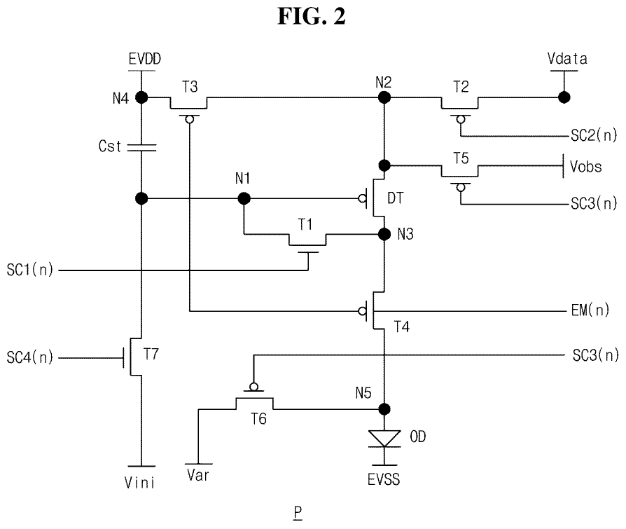

FIG. 1 is a view schematically illustrating a display apparatus according to a first embodiment of the present disclosure. FIG. 2 is a circuit diagram schematically illustrating an example of a pixel according to a first embodiment of the present disclosure.

Prior to a specific description, the display apparatus 10 according to the present embodiment can be one of all types of display apparatuses, including a light emitting display apparatus having a light emitting diode, in which a hole H is formed within a display region AA of a display panel 100.

Meanwhile, for convenience of explanation, in this embodiment, an organic light emitting display apparatus is described as an example of the display apparatus 10.

Referring to FIG. 1, the display apparatus 10 according to the present embodiment can include a display panel 100 and an optical component arranged below the hole H formed in the display panel 100. The display panel 100 can include the display region AA that displays an image and a non-display region NA disposed outside the display region AA (or disposed along a periphery of the display region AA).

In the display region AA, the hole H in which the optical component is arranged and which actually serves as a non-display region NA is formed. The optical component arranged in the hole H can include, for example, an imaging sensor such as a camera, a distance detection sensor, a face recognition sensor, etc., but not limited thereto. Meanwhile, in this embodiment, a case in which the hole H is configured in a horizontally symmetrical shape is taken as an example.

As such, since the optical component can be arranged corresponding to the hole H of the display panel 100, a width of a bezel, which is the non-display region NA around the display region AA, can be reduced. Accordingly, the display region AA can be relatively expanded (or widened), and thus a user's screen immersion can be increased.

The display panel 100 with the hole H formed therein can be referred to as a hole-in display panel 100.

Meanwhile, in this embodiment, for convenience of explanation, the display region AA of the display panel 100 can be defined by dividing it based on the position of the hole H.

In this regard, for example, a portion of the display region AA, with the hole H formed therein, which is located on the left and right sides of the hole H in a horizontal direction (or row direction or first direction) can be referred to as a hole-in display region (or first display region) AA_HI. In other words, a portion of the display region AA that extends along the horizontal direction corresponding to the hole H and is located on both the left and right sides of the hole H can be the hole-in display region AA_HI.

In addition, a portion of the display region AA having no hole therein, which is located on an upper side and a lower side of the hole-in display region AA_HI can be referred to as a non-hole display region (or second display region) AA_NH. In other words, a portion of the display region AA located above and below the hole H and having no hole H formed inside it can be the non-hole display region AA_NH.

Furthermore, the hole-in display region AA_HI can be configured of two regions, a first region (or first hole-in display region) AA_HI1 and a second region (or second hole-in display region) AA_HI2, located on the left and right sides of the hole H. In this embodiment, for convenience of explanation, the hole-in display region AA_HI located on the left side of the hole H is referred to as the first region AA_HI1, and the hole-in display region AA_HI located on the right side of the hole H is referred to as the second region AA_HI2.

In addition, the non-hole display region AA_NH can be configured of two regions, a third region (or first non-hole display region) AA_NH1 and a fourth region (or second non-hole display region) AA_NH2, located on the upper and lower sides of the hole H. In this embodiment, for convenience of explanation, the non-hole display region AA_NH located on the upper side of the hole H is referred to as the third region AA_NH1, and the non-hole display region AA_NH located on the lower side of the hole H is referred to as the fourth region AA_NH2.

In the display region AA configured as above, a plurality of pixels P can be arranged in a matrix form along a plurality of horizontal lines (or row lines) and a plurality of vertical lines (or column lines).

Here, the plurality of pixels P can include pixels that display different colors, for example, red, green, and blue pixels that display red, green, and blue, respectively, but not limited thereto. For example, the plurality of pixels P may include a white pixel in addition to the red, green, and blue pixels.

In the display panel 100, various signal lines that transmit driving signals for driving the pixels P can be formed on a substrate.

In this regard, for example, a plurality of data lines that transmit data signals (or data voltages), which are image signals, can extend in the vertical direction and be connected to the pixels P of the respective vertical lines.

In addition, a gate line transmitting a gate signal (or gate voltage) can extend along the horizontal direction and be connected to the pixels P of the corresponding horizontal line.

In this embodiment, a plurality of gate signals can be used to drive each pixel P, for example, a first scan signal to a fourth scan signal and an emission control signal can be used. Accordingly, a plurality of gate lines respectively transmitting the plurality of gate signals can be used, for example, a first scan line to a fourth scan line and an emission control line can be used. The plurality of gate signals and gate lines are described in more detail below.

As such, the plurality of pixels P can be defined by a plurality of data lines and gate lines intersecting each other.

Each pixel P can include a light emitting diode as a light emitting element, and a plurality of transistors and at least one capacitor for driving the light emitting diode. Meanwhile, in this embodiment, for convenience of explanation, an 8T1C structure in which the pixel P is provided with eight transistors T1 to T7 and DT and one capacitor Cst, as illustrated in FIG. 2, is taken as an example.

Referring to FIG. 2, the pixel P can include a plurality of switching transistors i.e., first transistor T1 to seventh transistor T7, a driving transistor DT, a storage capacitor Cst, and a light emitting diode OD.

Each of the first to seventh transistors T1 to T7 and the driving transistor DT can include a first electrode, a second electrode, and a gate electrode. One of the first electrode and the second electrode can be a source electrode, and the other of the first electrode and the second electrode can be a drain electrode.

Each of the first to seventh transistors T1 to T7 and the driving transistor DT can be a P-type or N-type transistor. Meanwhile, in FIG. 2, a case in which the second, third, fourth, fifth, and sixth transistors T2, T3, T4, T5, and T6 are configured as P-type transistors, the first and seventh transistors T1 and T7 are configured as N-type transistors, and the driving transistor DT is configured as a P-type transistor is taken as an example, but not limited thereto.

The first to seventh transistors T1 to T7 and the driving transistor DT can include semiconductors of the same material or include semiconductors of different materials. In this regard, for example, some of the first transistor T1 to the seventh transistor T7 and the driving transistor DT can have one semiconductor layer among a polycrystalline silicon layer, an oxide semiconductor layer, and an amorphous silicon layer, and the other of the first transistor T1 to the seventh transistor T7 and the driving transistor DT can have another semiconductor layer among a polycrystalline silicon layer, an oxide semiconductor layer, and an amorphous silicon layer.

Meanwhile, since an oxide semiconductor has excellent off-current characteristics and thus can have characteristics suitable for a switching transistor, at least one of the first transistor T1 to the seventh transistor T7 can have an oxide semiconductor layer. In addition, since polycrystalline silicon has excellent mobility, the driving transistor DT can have a polycrystalline silicon layer. The first transistor T1 to the seventh transistor T7 and the driving transistor DT can be configured in another form.

The gate signals provided to a n-th horizontal line of FIG. 2 can be provided from a gate driving circuit. For example, the gate driving circuit can provide four scan signals i.e., first to fourth scan signals SC1(n) to SC4(n) and one emission control signal EM(n). In this case, the first to fourth scan lines and the emission control line that transmit the first to fourth scan signals SC1(n) to SC4(n) and the emission control signal EM(n) to the pixel P can be formed.

The first transistor T1 can function as a sampling transistor, the second transistor T2 can function as a data supply transistor, the third and fourth transistors T3, T4 can each function as an emission control transistor, the fifth transistor T5 can function as a bias transistor, and the sixth and seventh transistors T6 and T7 can each function as an initialization transistor.

The light emitting diode OD can include an anode electrode and a cathode electrode. The anode electrode of the light emitting diode OD can be connected to a fifth node N5, and the cathode electrode of the light emitting diode OD can be applied with a low-potential driving voltage EVSS.

The driving transistor DT can include a first electrode connected to a second node N2, a second electrode connected to a third node N3, and a gate electrode connected to a first node N1. The driving transistor DT can provide a driving current (or an emission current) to the light emitting diode OD based on a voltage of the first node N1 (i.e., the data voltage Vdata stored in the storage capacitor Cst).

The first transistor T1 can include a first electrode connected to the first node N1, a second electrode connected to the third node N3, and a gate electrode receiving the first scan signal SC1(n). The first transistor T1 can be turned on in response to the first scan signal SC1(n), and be diode-connected between the first node N1 and the third node N3, thereby sampling a threshold voltage Vth of the driving transistor DT, and also sampling (or applying) the data voltage Vdata to the gate electrode of the driving transistor DT.

The storage capacitor Cst can be connected between the first node N1 and a fourth node N4. The storage capacitor Cst can store or maintain a high-potential driving voltage EVDD provided thereto.

The second transistor T2 can include a first electrode connected to the data line DL (or, receiving the data voltage Vdata), a second electrode connected to the second node N2, and a gate electrode receiving the second scan signal SC2(n). The second transistor T2 can be turned on in response to the second scan signal SC2(n) and transmit the data voltage Vdata to the second node N2.

The third transistor T3 and the fourth transistor T4 (or, first and second emission control transistors) can be connected between a power line of the high-potential driving voltage EVDD and the light emitting diode OD and can form a current path along which the driving current generated by the driving transistor DT moves.

The third transistor T3 can include a first electrode connected to the fourth node N4 and receiving the high-potential driving voltage EVDD, a second electrode connected to the second node N2, and a gate electrode receiving the emission control signal EM(n).

The fourth transistor T4 can include a first electrode connected to the third node N3, a second electrode connected to the fifth node N5 (or the anode electrode of the light emitting diode OD), and a gate electrode receiving the emission control signal EM(n).

The third and fourth transistors T3 and T4 can be turned on in response to the emission control signal EM(n), and in this case, the driving current can be provided to the light emitting diode OD, and the light emitting diode OD can emit light with a luminance corresponding to the driving current.

The fifth transistor T5 can include a first electrode receiving a bias voltage Vobs, a second electrode connected to the second node N2, and a gate electrode receiving the third scan signal SC3(n).

The sixth transistor T6 can include a first electrode receiving an anode reset voltage Var, a second electrode connected to the fifth node N5, and a gate electrode receiving the third scan signal SC3(n).

The sixth transistor T6 can be turned on in response to the third scan signal SC3(n) before the light emitting diode OD emits light (or after the light emitting diode OD emits light), and can initialize (or reset) the anode electrode of the light emitting diode OD using the anode reset voltage Var.

The light emitting diode OD can have a parasitic capacitor formed between the anode electrode and the cathode electrode. In addition, while the light emitting diode OD emits light, the parasitic capacitor is charged so that the anode electrode of the light emitting diode OD can have a specific voltage. Therefore, by applying the anode reset voltage Var to the anode electrode of the light emitting diode OD through the sixth transistor T6, an amount of charge accumulated in the light emitting diode OD can be initialized.

In this embodiment, the gate electrodes of the fifth and sixth transistors T5 and T6 are configured to receive the third scan signal SC3(n) in common. However, it is not necessarily limited thereto, and the gate electrodes of the fifth and sixth transistors T5 and T6 can be configured to receive separate scan signals and be controlled independently.

The seventh transistor T7 can include a first electrode receiving an initialization voltage Vini, a second electrode connected to the first node N1, and a gate electrode receiving the fourth scan signal SC4(n).

The seventh transistor T7 can be turned on in response to the fourth scan signal SC4(n) and initialize the gate electrode of the driving transistor DT using the initialization voltage Vini. In this regard, unnecessary charges can remain in the gate electrode of the driving transistor DT due to the high-potential driving voltage EVDD applied to the storage capacitor Cst. Therefore, an amount of the remaining charges can be initialized by applying the initialization voltage Vini to the gate electrode of the driving transistor DT through the seventh transistor T7.

The 8T1C structure of the pixel P described above is an example, and the pixel P of this embodiment can be configured with a different structure.

The initialization voltage Vini that initializes the gate electrode of the driving transistor DT can be provided to the pixels P arranged in each horizontal line through, for example, an initialization voltage line VL arranged in each horizontal line of the display region AA.

Meanwhile, in this embodiment, a circuit structure of the initialization voltage line VL can be formed similarly between the hole-in display region AA_HI and the non-hole display region AA_NH. For example, similar to a resistor-capacitor (RC) structure of the initialization voltage line VL arranged in the non-hole display region AA_NH, which is a regular (or general) display region AA with no hole H formed inside, a RC structure of the initialization voltage line VL arranged in the hole-in display region AA_HI, which is an irregular display region AA with the hole H formed inside, can be implemented.

As such, when the RC characteristics of the initialization voltage line VL of the hole-in display region AA_HI is configured similarly (or approximately) to the RC characteristics of the initialization voltage line VL of the non-hole display region AA_NH, a difference i.e., a deviation, between a ripple component of the initialization voltage Vini of the hole-in display region AA_HI and a ripple component of the initialization voltage Vini of the non-hole display region AA_NH can be alleviated and improved.

In this regard, electrical coupling occurs between a transmission path of the initialization voltage Vini and a transmission path of a scan signal (e.g., at least one of the first to fourth scan signals SC1(n) to SC4(n)), and due to the electrical coupling, the scan signal can act on the initialization voltage Vini to generate a ripple. For example, the initialization voltage line VL is electrically coupled with a transmission line of the fourth scan signal SC4(n) applied to the seventh transistor T7 that is connected to the initialization voltage line VL, and thus a ripple can occur in the initialization voltage Vini at a time when the fourth scan signal SC4(n) falls.

A magnitude of the ripple of the initialization voltage Vini depends on the RC characteristic of the initialization voltage line VL.

In this embodiment, the RC characteristic of the initialization voltage line VL of the hole-in display region AA_HI is configured similarly to the RC characteristic of the initialization voltage line VL of the non-hole display region AA_NH, so that the deviation of the ripple component of the initialization voltage Vini between the non-hole display region AA_NH and the hole-in display region AA_HI can be alleviated.

Accordingly, the deviation of the ripple component of the initialization voltage Vini of the hole-in display region AA_HI compared to the non-hole display region AA_NH with respect to the horizontal direction can be reduced, so that the luminance difference i.e., the luminance deviation of the hole-in display region AA_HI compared to the non-hole display region AA_NH with respect to the horizontal direction can also be reduced. As such, since the luminance deviation between the non-hole display region AA_NH and the hole-in display region AA_HI along the horizontal direction is reduced, degradation of image quality in the hole-in display region AA_HI due to the luminance deviation can be improved.

An arrangement structure (or connection structure) of the initialization voltage line VL of the hole-in display region AA_HI that alleviates the luminance deviation and improves image quality is described in more detail below.

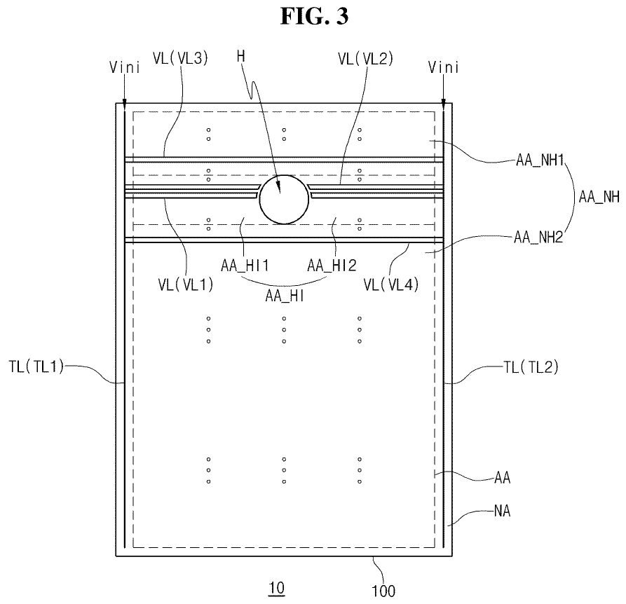

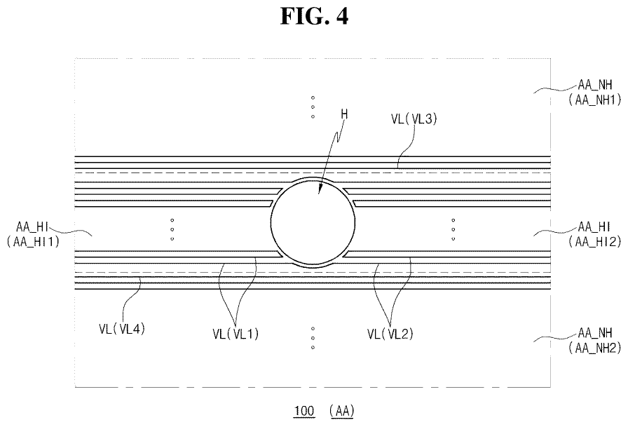

FIG. 3 is a view schematically illustrating an initialization voltage line and a voltage transmission line formed in a display panel according to a first embodiment of the present disclosure. FIG. 4 is a view schematically illustrating an example (or a first example) of an arrangement structure of an initialization voltage line formed in a hole-in display region and a non-hole display region according to a first embodiment of the present disclosure.

Referring to FIGS. 3 and 4 along with FIGS. 1 and 2, in the display panel 100 of this embodiment, voltage transmission lines TL that transmits the initialization voltage Vini can be arranged in a non-display region NA located on both sides of the display region AA, more specifically, on both sides, in the horizontal direction, of the display region AA.

In this regard, for example, the voltage transmission line TL that transmits the initialization voltage Vini supplied from a power circuit located outside the display panel 100 can be formed to extend along the vertical direction in each of the non-display region NA on the left and right sides of the display region AA.

In this embodiment, for convenience of explanation, the voltage transmission line TL arranged on the left side of the display region AA is referred to as a first voltage transmission line TL1, and the voltage transmission line TL arranged on the right side of the display region AA is referred to as a second voltage transmission line TL2.

In this way, the voltage transmission lines TL are arranged at edges on both sides of the display panel 100, so that the initialization voltage Vini can be applied to an inside of the display region AA from both sides of the display panel 100.

In the display region AA of the display panel 100, the initialization voltage line VL extending along each horizontal line can be formed. The initialization voltage line VL is connected to the voltage transmission line TL, receives the initialization voltage Vini from the voltage transmission line TL, and transmits it to the pixels P of each horizontal line.

Meanwhile, since the display panel 100 of this embodiment is provided with the hole H, the hole-in display region AA_HI with the hole H inside and the non-hole display region AA_NH without the hole H inside have a difference in the arrangement structure (or connection structure) of the initialization voltage line VL.

In this regard, for example, in the non-hole display region AA_NH of a regular form where the hole H is not formed, each initialization voltage line VL can be extended for each horizontal line.

More specifically, the initialization voltage line VL arranged in the non-hole display region AA_NH can be connected to the first voltage transmission line TL1 at one end (or a first end) of the initialization voltage line VL, and can be connected to the second voltage transmission line TL2 at the other end (or a second end) of the initialization voltage line VL so as to extend substantially across the display region AA along the horizontal direction.

Here, for convenience of explanation, the initialization voltage line VL arranged in the third region AA_NH1, which is the upper non-hole display region AA_NH with respect to the hole H, is referred to as a third initialization voltage line VL3, and the initialization voltage line VL arranged in the fourth region AA_NH2, which is the lower non-hole display region AA_NH with respect to the hole H, is referred to as a fourth initialization voltage line VL4.

In this case, each third initialization voltage line VL3 can extend along each horizontal line of the third region AA_NH1 and can be connected to the first and second voltage transmission lines TL1 and TL2 at both ends. Similarly, each fourth initialization voltage line VL4 can extend along each horizontal line of the fourth region AA_NH2 and can be connected to the first and second voltage transmission lines TL1 and TL2 at both ends.

Meanwhile, regarding the initialization voltage line VL arranged in the hole-in display region AA_HI, a plurality of unit groups can be formed with k (where k is an integer greater than or equal to 2) (or a plurality of or multiple) adjacent horizontal lines defining a unit group, and the k initialization voltage lines VL within the unit group can be configured to be connected to each other around the hole H. In other words, the initialization voltage lines VL of the k adjacent horizontal lines can be configured to form one connection group, and the k initialization voltage lines VL belonging to the connection group can be configured to be connected to each other around the hole.

In this regard, in this embodiment, a case, where the initialization voltage lines VL are connected with two adjacent horizontal lines as a unit in the hole-in display region AA_HI to form the connection group, is taken as an example.

In addition, for convenience of explanation, the initialization voltage line VL arranged in the first region AA_HI1, which is the left hole-in display region AA_HI with respect to the hole H, is referred to as a first initialization voltage line VL1, and the initialization voltage line VL arranged in the second region AA_HI2, which is the right hole-in display region AA_HI with respect to the hole H, is referred to as a second initialization voltage line VL2.

In this case, one end of the first initialization voltage line VL1 arranged in each horizontal line of the first region AA_HI1 can be connected to the first voltage transmission line TL1 adjacent to the first initialization voltage line VL1.

In addition, for at least some of N horizontal lines (or a first horizontal line to a N-th (or last) horizontal line) (where N is an integer greater than or equal to 4) in the first region AA_HI1, the first initialization voltage lines VL1 can be connected commonly in a unit of two adjacent horizontal lines to form the connection group.

In this embodiment, for convenience of explanation, for the second to N−1-th horizontal lines excluding the first horizontal line (i.e., the uppermost horizontal line of the hole-in display region AA_HI1) and the N-th horizontal line (i.e., the lowermost horizontal line of the hole-in display region AA_HI1), the first initialization voltage lines VL1 in a unit of two adjacent horizontal lines can be connected commonly to form the connection group.

In this regard, for example, the first initialization voltage lines VL1 (or the other ends thereof) located on the second and third horizontal lines can be connected to each other on the outside (i.e., the left) of the hole H. Similarly, the first initialization voltage lines VL1 (or the other ends thereof) located on the fourth and fifth horizontal lines can be connected to each other on the outside (i.e., the left) of the hole H. In this way, the first initialization voltage lines VL1 can be connected by using two horizontal lines as a unit of the connection group.

Meanwhile, the first initialization voltage line VL1 of the first horizontal line in the first region AA_HI1 can be connected to the second initialization voltage line VL2 of the first horizontal line in the second region AA_HI2 that is located on the opposite side with the hole H therebetween. For example, the first initialization voltage line VL1 and the second initialization voltage line VL2 located in the first horizontal line can be connected to each other by extending along an upper periphery of the hole H.

Similarly, the first initialization voltage line VL1 of the N-th horizontal line in the first region AA_HI1 can be connected to the second initialization voltage line VL2 of the N-th horizontal line in the second region AA_HI2 that is located on the opposite side with the hole H therebetween. For example, the first initialization voltage line VL1 and the second initialization voltage line VL2 located in the N-th horizontal line can be connected to each other by extending along a lower periphery of the hole H.

Meanwhile, the arrangement structure (or connection structure) of the second initialization voltage line VL2 in the second region AA_HI2 can be symmetrical with the arrangement structure (or connection structure) of the first initialization voltage line VL1 in the first region AA_HI1.

In this regard, one end of the second initialization voltage line VL2 arranged in each horizontal line of the second region AA_HI2 can be connected to the second voltage transmission line TL2 adjacent to the second initialization voltage line VL2.

In addition, for at least some of the N horizontal lines (or the 1st horizontal line to the N-th horizontal line) in the second region AA_HI2, the second initialization voltage lines VL2 can be commonly connected in a unit of two adjacent horizontal lines to form the connection group.

In this regard, the connection group may be formed symmetrically with the first region AA_HI1. For example, for the second to N−1-th horizontal lines excluding the first horizontal line and the N-th horizontal line, the second initialization voltage lines VL2 can be commonly connected to each other as a unit of two adjacent horizontal lines to form the connection group.

In this regard, the second initialization voltage lines VL2 (or the other ends thereof) located on the second and third horizontal lines can be connected to each other on the outside (i.e., the right) of the hole H. Similarly, the second initialization voltage lines VL2 (or the other ends thereof) located on the fourth and fifth horizontal lines can be connected to each other on the outside (i.e., the right) of the hole H. In this way, the second initialization voltage lines VL2 can be connected by using two horizontal lines as a unit of the connection group.

Meanwhile, as mentioned above, the second initialization voltage line VL2 of the first horizontal line in the second region AA_HI2 can be connected to the first initialization voltage line VL1 of the first horizontal line in the first region AA_HI1 that is located on the opposite side with the hole H therebetween.

In addition, the second initialization voltage line VL2 of the N-th horizontal line in the second region AA_HI2 can be connected to the first initialization voltage line VL1 of the N-th horizontal line in the first region AA_HI1 that is located on the opposite side with the hole H therebetween.

Meanwhile, as an example that is different from the aforementioned arrangement structure, for all horizontal lines within the first region AA_HI1, the connection group can be formed by commonly connecting the first initialization voltage lines VL1 in a unit of two adjacent horizontal lines, and in a symmetrical manner, the connection group can be formed by commonly connecting the second initialization voltage lines VL2 in a unit of two adjacent horizontal lines. In this case, the first and second initialization voltage lines VL1 and VL2 of the first horizontal line are not connected to each other, and the first and second initialization voltage lines VL1 and VL2 of the N-th horizontal line are not connected to each other.

As described above, in this embodiment, for the initialization voltage lines VL arranged in the hole-in display region AA_HI, more specifically, each of the first and second regions AA_HI1 and AA_HI2, the two adjacent horizontal lines are configured as the connection group to electrically connect the two adjacent initialization voltage lines VL.

Accordingly, the RC structure of the initialization voltage line VL in the hole-in display region AA_HI is similar to the RC structure of the initialization voltage line VL in the non-hole display region AA_NH.

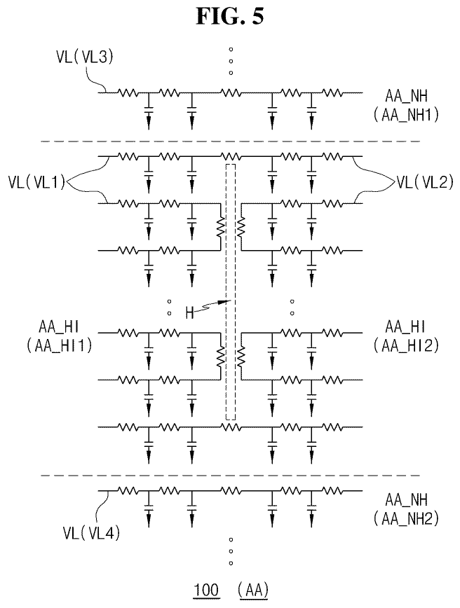

This refers to FIG. 5 together. FIG. 5 is a view schematically illustrating a circuit configuration of an initialization voltage line formed in a hole-in display region and a non-hole display region according to a first embodiment of the present disclosure.

Referring to FIG. 5 together with FIG. 4, in the first region AA_HI1 of the hole-in display region AA_HI, the first initialization voltage lines VL1 of the two adjacent horizontal lines are connected to form one connection group, and in the second region AA_HI2 of the hole-in display region AA_HI, the second initialization voltage lines VL2 of the two adjacent horizontal lines are connected to form one connection group.

In this case, the two first initialization voltage lines VL1 of each connection group can function substantially as one initialization voltage line in the first region AA_HI1, and the two second initialization voltage lines VL2 of each connection group can function substantially as one initialization voltage line in the second region AA_HI2.

As such, the circuit structure, more specifically, the RC structure of the two first initialization voltage lines VL1 constituting each connection group in the first region AA_IH1 is approximate to the RC structure of the initialization voltage line (VL: VL3 or VL4) of each horizontal line in the non-hole display region AA_NH. Likewise, the circuit structure, more specifically, the RC structure of the two second initialization voltage lines VL2 constituting each connection group in the second region AA_IH2 approximates the RC structure of the initialization voltage line (VL: VL3 or VL4) of each horizontal line in the non-hole display region AA_NH.

As such, the RC structure of the initialization voltage line (VL: VL1 or VL2) in the hole-in display region AA_HI is approximate to the RC structure of the initialization voltage line (VL: VL3 or VL4) of each horizontal line in the non-hole display region AA_NH.

Therefore, the RC characteristics of the initialization voltage wire VL of the hole-in display region AA_HI with the hole H inside is approximate to the RC characteristics of the initialization voltage line VL of the non-hole display region AA_NH with a regular form.

Accordingly, the deviation between the ripple component of the initialization voltage Vini of the hole-in display region AA_HI and the ripple component of the initialization voltage Vini of the non-hole display region AA_NH can be significantly alleviated.

As a result, the deviation of the ripple component of the initialization voltage Vini of the hole-in display region AA_HI compared to the non-hole display region AA_NH with respect to the horizontal direction can be reduced, and the luminance difference i.e., the luminance deviation of the hole-in display region AA_HI compared to the non-hole display region AA_NH with respect to the horizontal direction can also be reduced.

As such, by reducing the luminance deviation between the non-hole display region AA_NH and the hole-in display region AA_HI with respect to the horizontal direction, the degradation of image quality in the hole-in display region AA_HI due to the luminance deviation in the horizontal direction can be improved.

Meanwhile, the above example describes the method of configuring the multiple connection groups by connecting the initialization voltage lines VL in units of two adjacent horizontal lines in the hole-in display region AA_HI. This is an example, and the multiple connection groups can be configured by connecting the initialization voltage lines VL in units of three or more adjacent horizontal lines.

An example of a structure in which the initialization voltage lines VL are connected in a unit of four adjacent horizontal lines is described below.

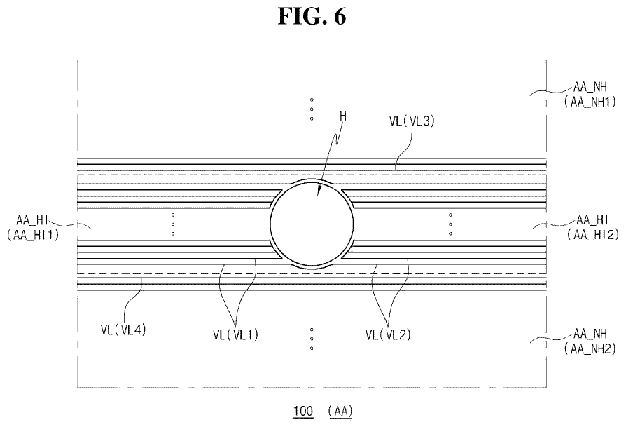

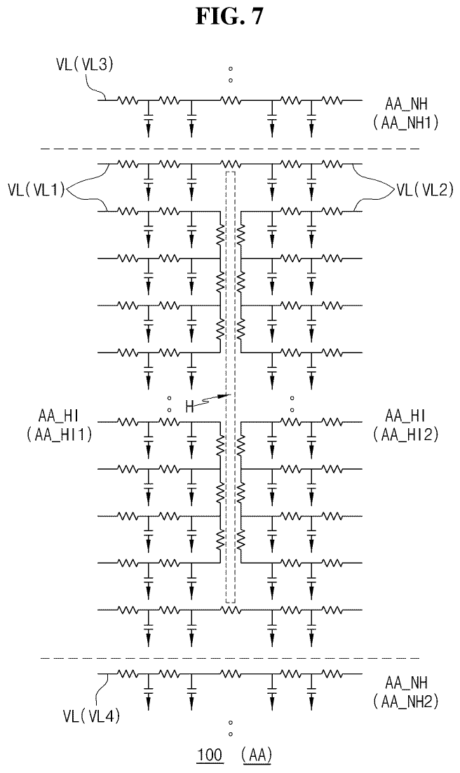

FIG. 6 is a view schematically illustrating another example (or second example) of an arrangement structure of an initialization voltage line formed in a hole-in display region and a non-hole display region according to a first embodiment of the present disclosure. FIG. 7 is a view schematically illustrating a circuit configuration of an initialization voltage line formed in a hole-in display region and a non-hole display region according to another example of FIG. 6.

Referring to FIGS. 6 and 7, the initialization voltage lines VL can be connected in a unit of four adjacent horizontal lines in the hole-in display region AA_HI to form a connection group.

In this regard, in the first region AA_HI1 of the hole-in display region AA_HI, for the second to N−1-th horizontal lines excluding the first horizontal line and the N-th horizontal line, the first initialization voltage lines VL1 can be commonly connected in a unit of four adjacent horizontal lines to form the connection group.

For example, the first initialization voltage lines VL1 (or the other ends thereof) located on the second to fifth horizontal lines can be connected to each other on the outside (i.e., the left) of the hole H. Similarly, the first initialization voltage lines VL1 (or the other ends thereof) located on the sixth to ninth horizontal lines can be connected to each other on the outside (i.e., the left) of the hole H. In this way, the first initialization voltage lines VL1 can be connected with four horizontal lines as a unit of the connection group.

Meanwhile, the first initialization voltage line VL1 of the first horizontal line in the first region AA_HI1 can be connected to the second initialization voltage line VL2 of the first horizontal line in the second region AA_HI2 located on the opposite side with the hole H therebetween.

Similarly, the first initialization voltage line VL1 of the N-th horizontal line in the first region AA_HI1 can be connected to the second initialization voltage line VL2 of the N-th horizontal line in the second region AA_HI2 located on the opposite side with the hole H therebetween.

Meanwhile, the arrangement structure of the second initialization voltage line VL2 in the second region AA_HI2 can be symmetrical with the arrangement structure of the first initialization voltage line VL1 in the first region AA_HI1.

In this regard, in the second region AA_HI2 of the hole-in display region AA_HI, for the second to N−1-th horizontal lines excluding the first and N-th horizontal lines, the second initialization voltage lines VL2 can be commonly connected in a unit of four adjacent horizontal lines to form the connection group.

For example, the second initialization voltage lines VL2 (or the other ends thereof) located on the second to fifth horizontal lines can be connected to each other on the outside (i.e., the right) of the hole H. Similarly, the second initialization voltage lines VL2 (or the other ends thereof) located on the sixth to ninth horizontal lines can be connected to each other on the outside (i.e., the right) of the hole H. In this way, the second initialization voltage lines VL2 can be connected by using four horizontal lines as a unit of the connection group.

Meanwhile, as an example different from the above arrangement structure, for all horizontal lines within the first region AA_HI1, the first initialization voltage lines VL1 can be commonly connected in a unit of four adjacent horizontal lines to form the connection group, and in a symmetrical manner, the second initialization voltage lines VL2 can be commonly connected in a unit of four adjacent horizontal lines to form the connection group. In this case, the first and second initialization voltage lines VL1 and VL2 of the first horizontal line are not connected to each other, and the first and second initialization voltage lines VL1 and VL2 of the N-th horizontal line are not connected to each other.

As above, for the initialization voltage lines VL arranged in the hole-in display region AA_HI, more specifically, each of the first and second regions AA_HI1 and AA_HI2, the four adjacent horizontal lines are configured as the connection group to electrically connect the four adjacent initialization voltage lines VL.

Accordingly, the RC structure of the initialization voltage line VL in the hole-in display region AA_HI becomes similar to the RC structure of the initialization voltage line VL in the non-hole display region AA_NH.

Here, the RC structure of the case where the four horizontal lines are configured as the connection group is lower in approximation to the RC structure of the initialization voltage line VL in the non-hole display region AA_NH as compared to the RC structure of the case where the two horizontal lines are configured as the connection group. Nevertheless, the deviation between the ripple component of the initialization voltage Vini in the hole-in display region AA_HI and the ripple component of the initialization voltage Vini in the non-hole display region AA_NH can be sufficiently alleviated.

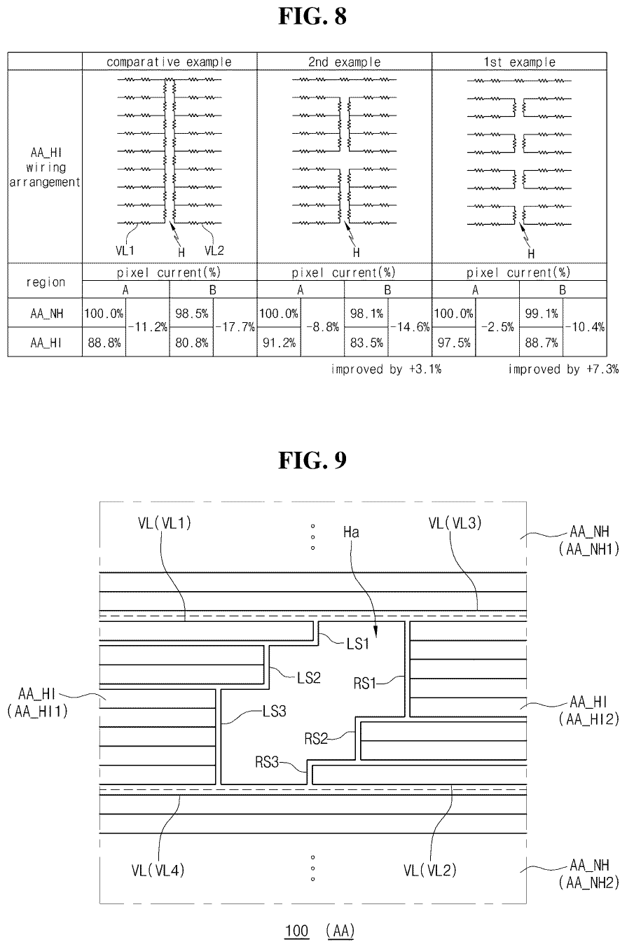

FIG. 8 is a view illustrating simulation results comparing pixel currents in arrangement structures of initialization voltage lines according to a first embodiment of the present disclosure and a comparative example.

In a display panel of the comparative example of FIG. 8, the initialization voltage lines of all horizontal lines of the hole-in display region AA_HI are connected. In other words, the first initialization voltage lines VL1 of all horizontal lines of the first region AA_HI1 are connected, the second initialization voltage lines VL2 of all horizontal lines of the second region AA_HI2 are connected, the first and second initialization voltage lines VL1 and VL2 of the first horizontal line are connected to each other, and the first and second initialization voltage lines VL1 and VL2 of the N-th (or last) horizontal line are connected to each other.

In the display panel of the first example of the embodiment of FIG. 8, as described above, the initialization voltage lines are connected in units of two horizontal lines. In addition, in the display panel of the second example of the embodiment of FIG. 8, as described above, the initialization voltage lines are connected in units of four horizontal lines.

Meanwhile, in the simulation of FIG. 8, a region “A” is a region near an edge of the display region AA in the horizontal direction, and a region “B” is a region near a center of the display region AA in the horizontal direction.

In addition, in the simulation of FIG. 8, a pixel current (i.e., driving current) located in the region “A” of the non-hole display region AA_NH of a regular form is set as 100% (i.e., reference), and pixel currents in the region “A” and the region “B” of the non-hole display region AA_NH and pixel currents in the region “A” and the region “B” of the hole-in display region AA_HI are measured.

Looking at FIG. 8, in the comparative example, the pixel current in the region “A” of the hole-in display area AA_HI is 88.8%, and a difference i.e., a deviation in pixel current between the non-hole display region AA_NH and the hole-in display region AA_HI with respect to the region “A” is −11.2%. In addition, the deviation in pixel current between the non-hole display region AA_NH and the hole-in display region AA_HI with respect to the region “B” is −17.7%. As such, in the comparative example, the deviation in pixel current becomes significantly larger as it goes from the region “A” to the region “B”. Accordingly, the luminance deviation becomes significantly larger as it goes toward the center along the horizontal direction, which severely deteriorates the image quality of the hole-in display region AA_HI in the horizontal direction.

On the other hand, in the first example of this embodiment, the pixel current in the region “A” of the hole-in display region AA_HI is 97.5%, and a difference i.e., a deviation in pixel current between the non-hole display region AA_NH and the hole-in display region AA_HI with respect to the region “A” is very small at −2.5%. In addition, the deviation in pixel current between the non-hole display region AA_NH and the hole-in display region AA_HI with respect to the region “B” is −10.4%, which is significantly reduced compared to the comparative example. As such, compared to the comparative example, in the first example of the embodiment, the deviation in pixel current is significantly reduced as it goes from the region “A” to the region “B”. Accordingly, compared to the comparative example, the luminance deviation is significantly reduced as it goes toward the center along the horizontal direction, so that the degradation of image quality of the hole-in display region AA_HI in the horizontal direction can be significantly improved.

In addition, in the second example of this embodiment, the pixel current of the hole-in display region AA_HI in the region “A” is 91.2%, and a difference i.e., a deviation in pixel current between the non-hole display region AA_NH and the hole-in display region AA_HI with respect to the region “A” is small at −8.8%. In addition, the deviation in pixel current between the non-hole display region AA_NH and the hole-in display region AA_HI with respect to the region “B” is −14.6%, which is reduced compared to the comparative example. As such, compared to the comparative example, in the second example of the embodiment, the deviation in pixel current is reduced as it goes from the region “A” to the region “B”. Accordingly, compared to the comparative example, the luminance deviation is reduced as it goes toward the center along the horizontal direction, so that the deterioration of image quality of the hole-in display region AA_HI in the horizontal direction can be improved.

### Second Embodiment

FIG. 9 is a view schematically illustrating an example of an arrangement structure of an initialization voltage line formed in a hole-in display region and a non-hole display region of a display panel according to a second embodiment of the present disclosure.

In the following description, specific explanations of configurations identical to or similar to those of the first embodiment described above can be omitted.

Referring to FIG. 9, in the display region AA of the display panel 100 of this embodiment, a hole Ha in asymmetrical form can be formed.

In this regard, for example, the hole Ha provided in the hole-in display region AA_HI can be configured in a form that is asymmetrical on the left and right. For example, the left boundary (or first boundary) of the hole Ha can have a step shape in which a side length of step increases as it goes downward, and the right boundary (or second boundary) of the hole Ha can have a step shape in which a side length of step increases as it goes upward.

Here, in this embodiment, an example is given in which the left boundary has left first side LS1 to left third side LS3 having three different lengths, and the right boundary has right first side RS1 to right third side RS3 having three different lengths. In this case, the left first side LS1 to left third side LS3 increase in length in that order, and the right first side RS1 to right third side RS3 decrease in length in that order.

In this case, a number of neighboring initialization voltage lines VL that are commonly connected within the hole-in display region AA_HI can be determined according to the length of the corresponding side of the hole Ha.

In this regard, for example, in the left first region AA_HI1, with respect to the left first side LS1 of the hole Ha, the first initialization voltage lines VL1 of two horizontal lines on which the left first side LS1 is located can be connected to each other to form the corresponding connection group. In addition, with respect to the left second side LS2 of the hole Ha, the first initialization voltage lines VL1 of three horizontal lines on which the left second side LS2 is located can be connected to each other to form the corresponding connection group. In addition, with respect to the left third side LS3 of the hole Ha, the first initialization voltage lines VL1 of six horizontal lines on which the left third side LS3 is located can be connected to each other to form the corresponding connection group.

Meanwhile, in the right second region AA_HI2, with respect to the right first side RS1 of the hole Ha, the second initialization voltage lines VL2 of six horizontal lines on which the right first side RS1 is located can be connected to each other to form the corresponding connection group. In addition, with respect to the right second side RS2 of the hole Ha, the second initialization voltage lines VL2 of three horizontal lines on which the right second side RS2 is located can be connected to each other to form the corresponding connection group. In addition, with respect to the right third side RS3 of the hole Ha, the second initialization voltage lines VL2 of two horizontal lines on which the right third side RS3 is located can be connected to each other to form the corresponding connection group.

As such, when the asymmetrical hole Ha is provided in the hole-in display region AA_HI, the connection structure of the initialization voltage line VL of the hole-in display region AA_HI can be configured to correspond to the asymmetrical shape of the hole Ha.

By configuring the connection structure of the initialization voltage line VL of the hole-in display region AA_HI asymmetrically to reflect the shape of the asymmetrical hole Ha, the luminance deviation of the hole-in display region AA_HI with the asymmetrical hole Ha formed therein compared to the non-hole display region AA_NH with respect to the horizontal direction can be reduced. Therefore, the deterioration of image quality of the hole-in display region AA_HI due to the luminance deviation in the horizontal direction can be improved.

As described above, according to the embodiments of the present disclosure, regarding the initialization voltage lines arranged in the hole-in display region with the hole formed inside, the adjacent horizontal lines can be configured as a unit connection group, and the initialization voltage lines belonging to the connection group can be connected to each other near the hole.

Therefore, the RC structure of the initialization voltage line in the hole-in display region becomes approximate to the RC structure of the initialization voltage line in the non-hole display region.

Accordingly, the deviation between the ripple component of the initialization voltage in the hole-in display region and the ripple component of the initialization voltage in the non-hole display region can be significantly alleviated, so that the luminance deviation of the hole-in display region compared to the non-hole display region in the horizontal direction can be reduced.

Therefore, the deterioration of image quality in the hole-in display region due to the luminance deviation in the horizontal direction can be improved.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. A display apparatus, comprising:
a display panel including a hole and a display region in which pixels are arranged; and
initialization voltage lines that extend along horizontal lines of the display region, respectively, the initialization voltage lines providing an initialization voltage to the pixels,
wherein the display region includes a first display region including a first region and a second region arranged on both sides in a horizontal direction with the hole therebetween, and a second display region including a third region and a fourth region arranged on both sides in a vertical direction with the hole therebetween,
wherein the initialization voltage lines include a first initialization voltage line to a fourth initialization voltage line respectively arranged in the first region to the fourth region,
wherein the first region includes a plurality of connection groups in each of which adjacent first initialization voltage lines are commonly connected, and
wherein the second region includes a plurality of connection groups in each of which adjacent second initialization voltage lines are commonly connected.

2. The display apparatus of claim 1, wherein the hole has a symmetrical shape with respect to the horizontal direction, and a connection structure of the adjacent first initialization voltage lines of the first region is symmetrical with a connection structure of the adjacent second initialization voltage lines of the second region.

3. The display apparatus of claim 1, wherein a number of the adjacent first initialization voltage lines constituting a connection group from the plurality of connection groups of the first region is k, where k is an integer greater than or equal to 2, and a number of the adjacent second initialization voltage lines constituting a connection group from the plurality of connection groups of the second region is k.

4. The display apparatus of claim 1, wherein the first initialization voltage line and the second initialization voltage line located in a first horizontal line of the first display region are connected to each other, and the first initialization voltage line and the second initialization voltage line located in a N-th horizontal line as a last horizontal line of the first display region are connected to each other.

5. The display apparatus of claim 4, wherein in second to N−1-th horizontal lines of the first display region,
wherein the adjacent first initialization voltage lines are commonly connected to each of the plurality of connection groups of the first region, and the adjacent second initialization voltage lines are commonly connected to each of the plurality of connection groups of the second region.

6. The display apparatus of claim 1, further comprising:
a first voltage transmission line and a second voltage transmission line extending along the vertical direction in a non-display region on both sides of the display region, respectively, and transmitting the initialization voltage.

7. The display apparatus of claim 6, wherein each of the third initialization voltage line and the fourth initialization voltage line is connected to the first voltage transmission line and the second voltage transmission line at both ends thereof, and
wherein the first initialization voltage line is connected to the first voltage transmission line at one end thereof, and the second initialization voltage line is connected to the second voltage transmission line at one end thereof.

8. The display apparatus of claim 1, wherein the hole has an asymmetrical shape with respect to the horizontal direction, and
wherein a connection structure of the adjacent first initialization voltage lines of the first region is asymmetrical with a connection structure of the adjacent second initialization voltage lines of the second region.

9. The display apparatus of claim 8, wherein a first side boundary of the hole corresponding to the first region includes sides of different lengths, and
wherein the adjacent first initialization voltage lines of the horizontal lines where one of the sides of the first side boundary is located are connected to each other and form a corresponding connection group of the first region.

10. The display apparatus of claim 8, wherein a second side boundary of the hole corresponding to the second region includes sides of different lengths, and
wherein the adjacent second initialization voltage lines of the horizontal lines where one of the sides of the second side boundary is located are connected to each other and form a corresponding connection group of the second region.

11. The display apparatus of claim 1, wherein a pixel from the pixels includes:
a light emitting diode;
a driving transistor that provides a driving current to the light emitting diode; and
an initialization transistor connected to the driving transistor and an initialization voltage line from the initialization voltage lines.

12. A display apparatus, comprising:
a display panel including a hole and a display region in which pixels are arranged; and
initialization voltage lines that extend along horizontal lines of the display region, respectively, the initialization voltage lines providing an initialization voltage to the pixels,
wherein the display region includes a first display region with the hole located therein and extending in a horizontal direction, and a second display region outside the first display region, and
wherein each of both portions of the first display region on both sides of the hole includes a plurality of connection groups in each of which the initialization voltage lines of adjacent horizontal lines are commonly connected.

13. The display apparatus of claim 12, wherein the hole has a symmetrical shape with respect to the horizontal direction, and connection structures of the initialization voltage lines of the both portions of the first display region on the both sides of the hole are symmetrical with each other.

14. The display apparatus of claim 12, wherein a number of the initialization voltage lines constituting a connection group from the plurality of connection groups of each of the both portions of the first display region on the both sides of the hole is k, where k is an integer greater than or equal to 2.

15. The display apparatus of claim 12, wherein the hole has an asymmetrical shape with respect to the horizontal direction, and connection structures of the initialization voltage lines of the both portions of the first display region on the both sides of the hole are asymmetrical with each other.

16. The display apparatus of claim 12, wherein a pixel from the pixels includes:
a light emitting diode;
a driving transistor that provides a driving current to the light emitting diode; and
an initialization transistor connected to the driving transistor and an initialization voltage line from the initialization voltage lines.

17. The display apparatus of claim 1, wherein the initialization voltage lines are connected in a unit of two or four adjacent horizontal lines.

18. The display apparatus of claim 12, wherein the initialization voltage lines are connected in a unit of two or four adjacent horizontal lines.

19. The display apparatus of claim 8, wherein a first boundary of the hole has a step shape in which a side length of a step increases as it goes downward, and a second boundary of the hole has a step shape in which a side length of a step increases as it goes upward.

20. The display apparatus of claim 15, wherein a first boundary of the hole has a step shape in which a side length of a step increases as it goes downward, and a second boundary of the hole has a step shape in which a side length of a step increases as it goes upward.
